(19) United States
(12) Patent Application Publication
(10) Pub. No.: US 2020/0236824 A1
(43) Pub. Date: Jul. 23, 2020

(54) POWER CONVERSION DEVICE

(71) Applicant: TOYOTA JIDOSHA KABUSHIKI KAISHA, Toyota-shi (JP)

(72) Inventor: Naoya ODASHIMA, Toyota-shi (JP)

(73) Assignee: TOYOTA JIDOSHA KABUSHIKI KAISHA, Toyota-shi (JP)

(21) Appl. No.: 16/694,196

(22) Filed: Nov. 25, 2019

(30) Foreign Application Priority Data
Jan. 18, 2019 (JP) 2019-007116

(51) Int. Cl. H05K 7/20; H02M 3/158

(52) U.S. Cl. CPC H05K 7/20945; H02M 3/1584; H02P 27/06; H05K 7/20872; H05K 7/20927

(57) ABSTRACT

A power conversion device is configured to reduce the number of temperature sensors that are to be mounted to the power conversion device. The power conversion device has a plurality of reactors and a cooling flow path in which the plurality of reactors are placed sequentially. The power conversion device is configured to convert electric power from a power storage device. The power conversion device further includes a temperature sensor that is mounted to only part of reactors including a reactor having a highest thermal resistance out of the plurality of reactors. A reactor having the higher thermal resistance has a larger degree of a variation in temperature than the degree of a variation in temperature of a reactor having the lower thermal resistance. Accordingly, the configuration of detecting the temperature of the reactor having the higher thermal resistance increases the sensitivity of control and implements the more appropriate control.

### CROSS-REFERENCE TO RELATED APPLICATION

This application claims priority to Japanese Patent Application No. 2019-007116 filed on Jan. 18, 2019, the contents of which is incorporated herein by reference.

### TECHNICAL FIELD

The present disclosure relates to a power conversion device or more specifically to a power conversion device including a cooling flow path in which a plurality of reactors are sequentially placed.

### BACKGROUND

A proposed configuration of a power conversion device has a plurality of heat-generating electronic components that are placed in a descending order of maximum heat-generating temperature in a cooling flow path from an upstream side toward a downstream side (as described in, for example, JP 2017-152612A). This power conversion device has a first boost circuit including a first capacitor and a first reactor and a second boost circuit including a second capacitor and a second reactor. A plurality of components selected among the first capacitor, the first reactor, the second capacitor and the second reactor are specified as the heat-generating electronic components.

### CITATION LIST

### Patent Literature

PTL 1: JP2017-152612A

When the plurality of reactors are sequentially placed in the cooling flow path, one applicable configuration may mount a temperature sensor to each of the reactors, with a view to checking whether the temperature of each reactor does not reach an allowable maximum temperature. This configuration, however, increases the total number of components and requires complicated management. Another available configuration that does not mount the temperature sensor to part of the reactors, on the other hand, fails in detecting the occurrence of abnormal heat generation in a reactor equipped without the temperature sensor.

### SUMMARY

A main object of a power conversion device of the present disclosure is to reduce the number of temperature sensors that are to be mounted to the power conversion device.

In order to achieve the above primary object, the power conversion device of the disclosure is implemented by an aspect described below.

The present disclosure is directed to a power conversion device. The power conversion device includes a plurality of reactors and a cooling flow path in which the plurality of reactors is placed sequentially, the power conversion device being configured to convert electric power from a power storage device. The power conversion device further includes a temperature sensor that is mounted to only part of reactors including a reactor having a highest thermal resistance out of the plurality of reactors.

In the power conversion device according to this aspect of the present disclosure, the temperature sensor is mounted to only part of the reactors including the reactor having the highest thermal resistance out of the plurality of reactors that are placed sequentially in the cooling flow path. The temperature of the reactor having the highest thermal resistance is determined in advance when an abnormality occurs in a cooling system of a reactor having a lower thermal resistance and the reactor having the lower thermal resistance continuously has an allowable maximum temperature. The power conversion device is driven, such that the temperature of the reactor having the highest thermal resistance becomes equal to or lower than the determined temperature. This configuration causes the temperature of the reactor having the lower thermal resistance to become equal to or lower than the allowable maximum temperature and thereby enables the power conversion device to be driven without causing the occurrence of abnormal heat generation in any of the reactors. The temperature sensor is mounted to a reactor having the higher thermal resistance. This is because the degree of a variation in temperature of the reactor having the higher thermal resistance is larger than the degree of a variation in temperature of a reactor having the lower thermal resistance. Accordingly, a configuration of using a parameter having a larger degree of variation increases the sensitivity of the control and implements the more appropriate control, compared with a configuration of using a parameter having a smaller degree of variation. As a result, the configuration of this aspect reduces the number of temperature sensors that are to be mounted to the power conversion device. The “plurality of reactors” include reactors included in a plurality of boost circuits that are connected in parallel to each other and that are configured to step up voltage of the electric power from the power storage device and output the electric power of the stepped-up voltage.

### BRIEF DESCRIPTION OF DRAWINGS

FIG. 1 is a configuration diagram illustrating the schematic electrical configuration of an electric vehicle provided with a power conversion device according to one embodiment of the present disclosure;

FIG. 2 is a schematic configuration diagram mainly illustrating a cooling system-related configuration of the power conversion device;

FIG. 3 is a schematic plan view schematically illustrating one example of the planar configuration of an upper side flow path and a lower side flow path;

FIG. 4 is a graph showing one example of variations in flow rate sensitivities of a reactor L1 and a reactor L2;

FIG. 5 is a flowchart showing one example of an output restriction placing and removing process performed by an electronic control unit;

FIG. 6 is a graph illustrating one example of a relationship between temperature T1 of the reactor L1 and temperature T2 of the reactor L2 in the event of an abnormality in a cooling system of the reactor L2;

FIG. 7 is a graph illustrating one example of a correction factor setting map.

### DESCRIPTION OF EMBODIMENTS

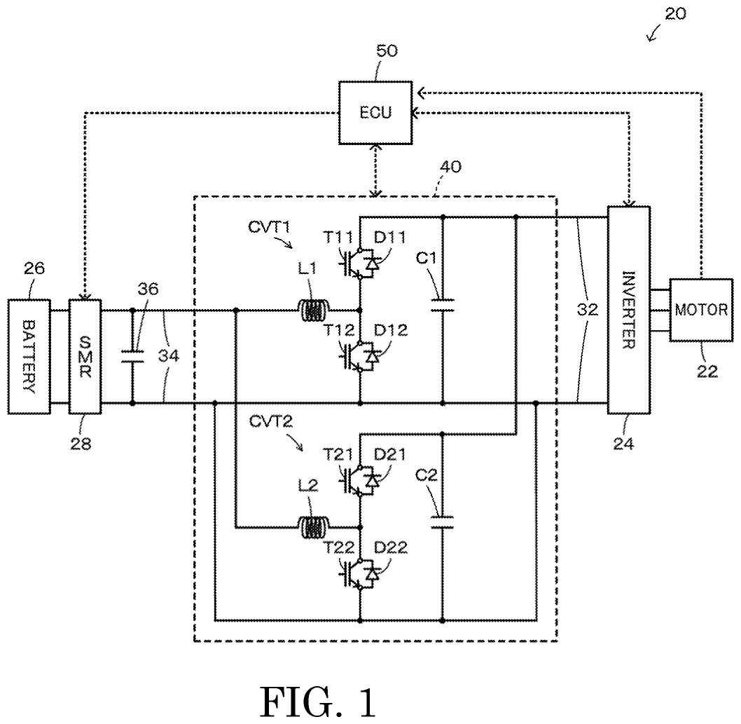

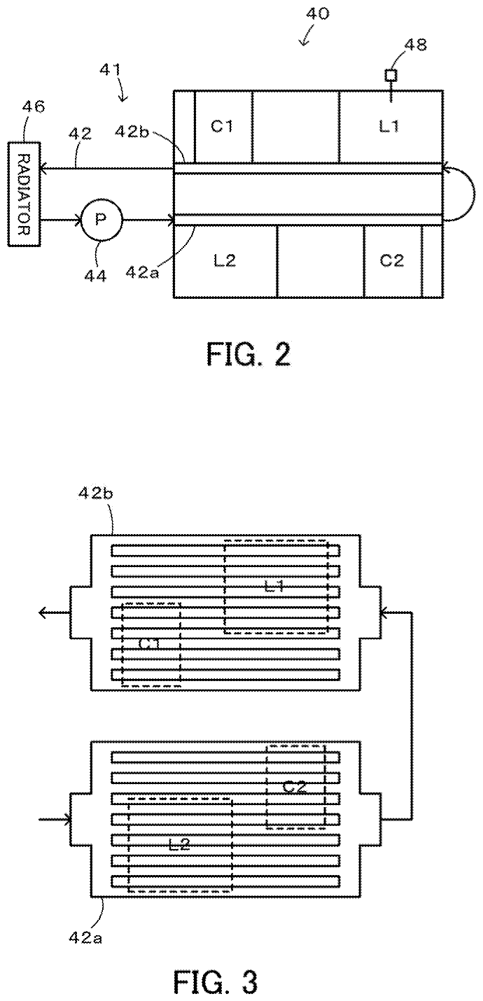

The following describes some aspects of the present disclosure with reference to an embodiment. FIG. 1 is a configuration diagram illustrating the schematic electrical configuration of an electric vehicle 20 provided with a power conversion device 40 according to one embodiment of the present disclosure. FIG. 2 is a configuration diagram mainly illustrating a cooling system-related configuration of the power conversion device 40. As shown in FIG. 1, the electric vehicle 20 of the embodiment includes a motor 22, an inverter 24, a battery 26 serving as a power storage device, the power conversion device 40 including a first boost converter CVT1 and a second boost converter CVT2, and an electronic control unit 50.

The motor 22 is configured as, for example, a synchronous generator motor and includes a rotor connected with a driveshaft that is linked with drive wheels via a differential gear, although not being illustrated. The inverter 24 is connected with the motor 22 and is also connected with high voltage-side power lines 32. The electronic control unit 50 performs switching control of a plurality of switching elements (not shown) included in the inverter 24 to drive and rotate the motor 22.

The battery 26 is configured as, for example, a lithium ion rechargeable battery or a nickel metal hydride battery and is connected with low voltage-side power lines 34. A system main relay 28 configured to connect and disconnect the battery 26 and a capacitor 36 for smoothing are mounted to both a positive electrode-side line and a negative electrode-side line of the low voltage-side power lines 34 in this sequence from the battery 26-side.

The power conversion device 40 includes a first boost converter CVT1, a second boost converter CVT2 and a cooling system 41 and is connected with the high voltage-side power lines 32 and with the low voltage-side power lines 34. The power conversion device 40 is configured to step up the voltage of electric power of the low voltage-side power lines 34 (i.e., voltage of electric power from the battery 26) and supply the electric power of the stepped-up voltage to the high voltage-side power lines 32 and to step down the voltage of electric power of the high voltage-side power lines 32 (i.e., voltage of electric power regenerated by the motor 22) and supply the electric power of the stepped-down voltage to the low voltage-side power lines 34-side.

The first boost converter CVT1 is connected with the high voltage-side power lines 32 and with the low voltage-side power lines 34 and is configured as a known step-up/down converter including two transistors T11 and T12, two diodes D11 and D12, a reactor L1 and a capacitor C1. The transistor T11 is connected with a positive electrode line of the high voltage-side power lines 32. The transistor T12 is connected with the transistor T11 and with negative electrode lines of the high voltage-side power lines 32 and of the low voltage-side power lines 34. The reactor L1 is connected with a connection point between the transistors T11 and T12 and with a positive electrode line of the low voltage-side power lines 34. The capacitor C1 is connected with the high voltage-side power lines 32 and with the low voltage-side power lines 34. The electronic control unit 50 regulates a ratio of the ON time of the transistor T11 to the ON time of the transistor T12 and thereby causes the first boost converter CVT1 to step up the voltage of the electric power of the low voltage-side power lines 34 and supply the electric power of the stepped-up voltage to the high voltage-side power lines 32 or to step down the voltage of the electric power of the high voltage-side power lines 32 and supply the electric power of the stepped-down voltage to the low voltage-side power lines 34.

The second boost converter CVT2 is configured as a step-up converter having substantially equivalent performances to those of the first boost converter CVT1, although employing a different material and a different mounting technique for its reactor L2. More specifically, like the first boost converter CVT1, the second boost converter CVT2 is connected with the high voltage-side power lines 32 and with the low voltage-side power lines 34 and is configured as a known step-up/down converter including two transistors T21 and T22, two diodes D21 and D22, a reactor L2 and a capacitor C2. The electronic control unit 50 regulates a ratio of the ON time of the transistor T21 to the ON time of the transistor T22 and thereby causes the second boost converter CVT2 to step up the voltage of the electric power of the low voltage-side power lines 34 and supply the electric power of the stepped-up voltage to the high voltage-side power lines 32 or to step down the voltage of the electric power of the high voltage-side power lines 32 and supply the electric power of the stepped-down voltage to the low voltage-side power lines 34.

As shown in FIG. 2, the cooling system 41 includes a cooling flow path 42 arranged to circulate a cooling medium (for example, water), a pump 44 provided to pressure-feed the cooling medium, and a radiator 46 configured to cool down the cooling medium by using the outside air. The cooling flow path 42 includes a lower side flow path 42a placed on a lower level to receive a supply of the cooling medium from the pump 44 and an upper side flow path 42b placed on a downstream side of the lower side flow path 42a. FIG. 3 is a schematic plan view schematically illustrating one example of the planar configuration of the upper side flow path 42b and the lower side flow path 42a. In FIG. 2 and FIG. 3, symbols L1 and L2 represent the reactors L1 and L2, and symbols C1 and C2 represent the capacitors C1 and C2. For example, as illustrated, each of the upper side flow path 42b and the lower side flow path 42a is configured such that the flow of the cooling medium is divided from a supply pool into a plurality of divisional flow paths and is joined together from the plurality of divisional flow paths into a discharge pool. The reactor L2 and the capacitor C2 of the second boost converter CVT2 are placed in the lower side flow path 42a such as to be cooled down in this sequence. The reactor L1 and the capacitor C1 of the first boost converter CVT1 are placed in the upper side flow path 42b such as to be cooled down in this sequence.

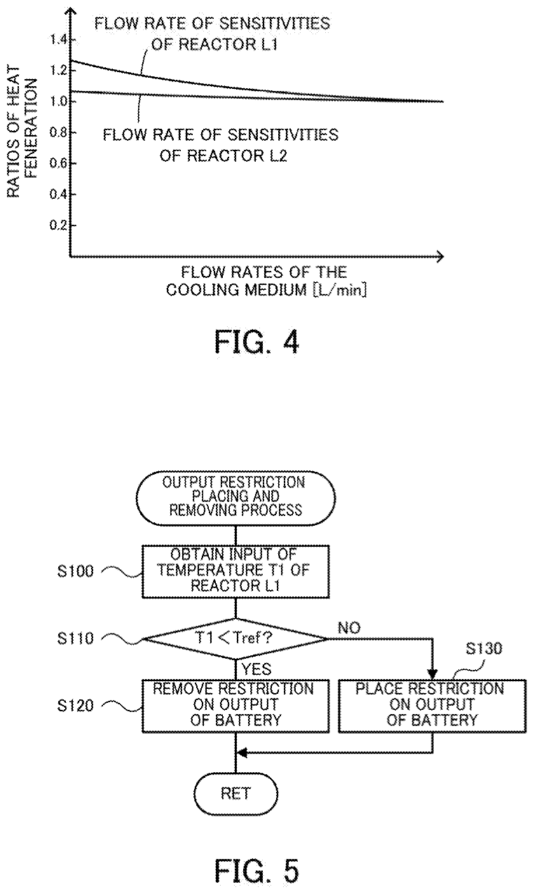

Different materials and different mounting techniques are employed for the reactor L1 of the first boost converter CVT1 and for the reactor L2 of the second boost converter CVT2 as described above. Accordingly, the reactor L1 and the reactor L2 have different thermal resistances. According to the embodiment, the reactor L1 and the reactor L2 are configured such that the reactor L1 has a higher thermal resistance than that of the reactor L2. The heat resistance herein is a value indicating a resistance to temperature transfer and is expressed as an amount of temperature rise by an amount of heat generation per unit time (unit of [K/W]). Accordingly, it is more difficult to cool down the reactor L1, compared with the reactor L2. One example of variations in flow rate sensitivities of the reactor L1 and the reactor L2 is shown in FIG. 4. FIG. 4 shows the flow rates [L/min] of the cooling medium flowing in the lower side flow path 42a and flowing in the upper side flow path 42b as the abscissa axis and shows ratios of heat generation of the reactor L1 and the reactor L2 as the ordinate axis. As clearly understood from the illustration, the reactor L1 has a lower thermal conductivity to the cooling medium (a higher thermal resistance) than that of the reactor L2.

The electronic control unit 50 is configured as a CPU-based microprocessor and includes a ROM configured to store processing programs, a RAM configured to temporarily store data, a non-volatile flash memory, and input/output ports in addition to the CPU, although not being illustrated.

As shown in FIG. 1, signals from various sensors are input into the electronic control unit 50 via the input port. The signals input into the electronic control unit 50 include, for example, a rotation position θm from a rotation position detection sensor (not shown) configured to detect a rotating position of the rotor of the motor 22 and phase currents Iu and Iv from current sensors (not shown) configured to detect electric currents flowing in respective phases of the motor 22. The input signals also include a voltage between terminals of the battery 26, an electric current Ib flowing in the battery 26, a temperature Tb of the battery 26, a voltage VH of the high voltage-side power lines 32 and a voltage VL of the low voltage-side power lines 34. The input signals further include an electric current IL1 flowing through the reactor L1 of the first boost converter CVT1, an electric current IL2 flowing through the reactor L2 of the second boost converter CVT2, and a reactor temperature T1 from a temperature sensor 48 mounted to the reactor L1 (shown in FIG. 2). Additionally, the input signals include an ignition signal from an ignition switch, a shift position from a shift position sensor configured to detect an operating position of a shift lever, an accelerator position Acc from an accelerator pedal position sensor configured to detect a depression amount of an accelerator pedal, a brake pedal position from a brake pedal position sensor configured to detect a depression amount of a brake pedal and a vehicle speed V from a vehicle speed sensor, although not being specifically illustrated.

As shown in FIG. 1, various control signals are output from the electronic control unit 50 via the output port. The signals output from the electronic control unit 50 include, for example, switching control signals to the plurality of switching elements included in the inverter 24, switching control signals to the transistors T11 and T12 of the first boost converter CVT1, switching control signals to the transistors T21 and T22 of the second boost converter CVT2, and a driving control signal to the system main relay 28.

The electronic control unit 50 calculates an electrical angle θe and a rotation speed Nm of the motor 22, based on the rotation position θm of the rotor of the motor 22. The electronic control unit 50 also calculates a state of charge SOC of the battery 26, based on an integrated value of the electric current Ib flowing in the battery 26, and calculates an input limit Win and an output limit Wout that represent maximum allowable powers to be charged into the battery 26 and to be discharged from the battery 26, based on the calculated state of charge SOC and the temperature Tb of the battery 26. The state of charge SOC herein denotes a ratio of the capacity of electric power dischargeable from the battery 26 to the overall capacity of the battery 26.

In the electric vehicle 20 of the embodiment having the configuration described above, the electronic control unit 50 performs driving control. More specifically, the electronic control unit 50 sets a required torque Tp* that is required for driving (i.e., required for the driveshaft 26), based on the accelerator position Acc and the vehicle speed V, sets the set required torque Tp* to a torque command Tm* of the motor 22, and performs switching control of the plurality of switching elements included in the inverter 24 such as to drive the motor 22 with the torque command Tm*.

The following describes a series of operations to place and remove a restriction on output of the battery 26, based on the temperature T1 of the reactor L1. FIG. 5 is a flowchart showing one example of an output restriction placing and removing process performed by the electronic control unit 50. This routine is performed repeatedly at predetermined time intervals (for example, at every one second or at every several seconds).

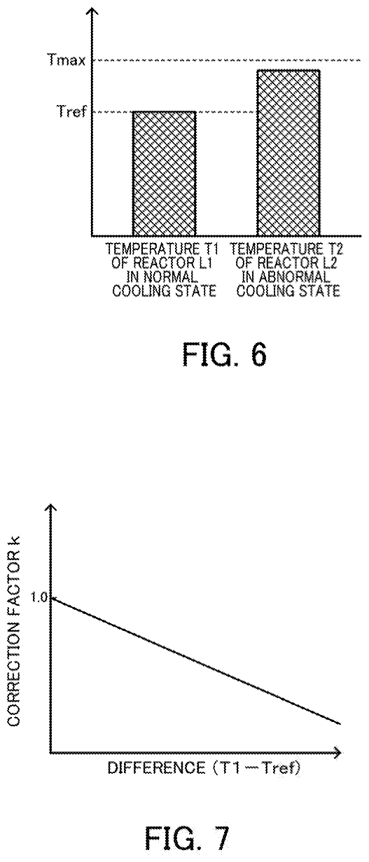

When the output restriction placing and removing process is triggered, the electronic control unit 50 first obtains the input of the temperature T1 of the reactor L1 from the temperature sensor 48 (step S100). The electronic control unit 50 subsequently determines whether the input temperature T1 is lower than a reference temperature Tref (step S110). The reference temperature Tref used may be a temperature of the reactor L1 when an abnormality occurs in the cooling system of the reactor L2 and the reactor L2 continuously has an allowable maximum temperature Tmax, or a slightly lower temperature than this temperature. For example, it is assumed that all the divisional flow paths adjacent to the reactor L2 are blocked by some foreign substance such as dust, out of the plurality of divisional flow paths of the lower side flow path 42a shown in FIG. 3. FIG. 6 shows a relationship between the temperature T1 of the reactor L1 and the temperature T2 of the reactor L2 in this case. In this case, when the temperature T1 of the reactor L1 is lower than the reference temperature Tref, the temperature T2 of the reactor L2 is equal to or lower than the allowable maximum temperature Tmax.

When it is determined at step S110 that the temperature T1 of the reactor L1 is equal to or higher than the reference temperature Tref, the electronic control unit 50 places a restriction on the output of the battery 26, in order to prevent the temperature of the reactor L2 from exceeding the allowable maximum temperature Tmax (step S130) and then terminates this process. The restriction on the output of the battery 26 is placed by restricting the output limit Wout of the battery 26 calculated by the electronic control unit 50, for example, by setting a product (k×Wout) of this output limit Wout and a k that is smaller than a value 1, as a working output limit Wout. Such restriction on the output of the battery 26 may be determined, such that the degree of the restriction is increased (i.e., the output limit Wout is multiplied by a smaller correction factor k) with an increase in a difference (T1−Tref) between the temperature T1 of the reactor L1 and the reference temperature Tref. An applicable procedure may determine in advance a relationship of the difference (T1−Tref) between the temperature T1 and the reference temperature Tref to the correction factor k, may store this relationship in the form of a correction factor setting map, and may read a correction factor k corresponding to a given difference (T1−Tref) from this map. One example of the correction factor setting map is shown in FIG. 7.

When it is determined at step S110 that the temperature T1 of the reactor L1 is lower than the reference temperature Tref, on the other hand, the electronic control unit 50 removes the restriction on the output of the battery when there is the restriction (step S120) and then terminates this process.

As described above, the temperature T1 of the reactor L1 having the higher thermal resistance is used for the above control. This is because the reactor L1 has the higher thermal resistance than that of the reactor L2, so that the degree of a variation in temperature T1 of the reactor L1 is larger than the degree of a variation in temperature T2 of the reactor L2. In other words, this is because the control using a parameter having a larger degree of variation more effectively increases the sensitivity of the control and implements the more appropriate control, compared with the control using a parameter having a smaller degree of variation. The reactor L1 having the higher thermal resistance is placed on the downstream side in the cooling flow path 42. This is because estimation of the temperature of a reactor placed on the upstream side having the larger cooling effect by using a parameter having a larger degree of variation in temperature on the downstream side having the smaller cooling effect increases the accuracy of the control, compared with estimation of the temperature of a reactor placed on the downstream side having the smaller cooling effect by using a parameter having a larger degree of variation in temperature on the upstream side having the larger cooling effect.

In the power conversion device 40 mounted on the electric vehicle 20 of the embodiment described above, the temperature sensor 48 is mounted to only the reactor L1 having the higher thermal resistance out of the two reactors L1 and L2. This configuration reduces the number of temperature sensors to be mounted to power conversion device 40, compared with a configuration that mounts temperature sensors to both the two reactors L1 and L2. The temperature sensor 48 is mounted to only the reactor L1 having the higher thermal resistance. This is because the reactor L1 has the higher thermal resistance than that of the reactor L2, so that the degree of a variation in temperature T1 of the reactor L1 is larger than the degree of a variation in temperature T2 of the reactor L2. Using only the temperature T1 of the reactor L1 input from the temperature sensor 48 thus enables the temperature T2 of the reactor L2 to become equal to or lower than the allowable maximum temperature Tmax.

Furthermore, in the power conversion device 40 mounted on the electric vehicle 20 of the embodiment, the reactor L2 having the lower thermal resistance is placed in the cooling flow path 42 such as to be cooled down by the lower side flow path 42a on the upstream side, and the reactor L1 having the higher thermal resistance is placed in the cooling flow path 42 such as to be cooled down by the upper side flow path 42b on the downstream side. This configuration increases the accuracy of the control and enables the temperature T2 of the reactor L2 to more appropriately become equal to or lower than the allowable maximum temperature Tmax.

Moreover, when the temperature T1 input from the temperature sensor 48 mounted to the reactor L1 having the higher thermal resistance is equal to or higher than the reference temperature Tref, the power conversion device 40 mounted on the electric vehicle 20 of the embodiment places the restriction on the output of the battery 26. Such control reduces the electric currents flowing through the reactors L1 and L2 of the power conversion device 40 and thereby suppresses temperature rises of the reactors L1 and L2.

In the power conversion device 40 of the embodiment, the reactor L2 having the lower thermal resistance is placed on the upstream side and the reactor L1 having the higher thermal resistance is placed on the downstream side in the cooling flow path 42. According to a modification, however, the reactor L1 having the higher thermal resistance may be placed on the upstream side and the reactor L2 having the lower thermal resistance may be placed on the downstream side in the cooling flow path 42. In other words, the flow of the cooling medium shown in FIG. 2 may be reversed. Even in this modification, using only the temperature T1 of the reactor L1 input from the temperature sensor 48 enables the temperature T2 of the reactor L2 to become equal to or lower than the allowable maximum temperature Tmax.

In the power conversion device 40 of the embodiment, the two reactors L1 and L2 are sequentially placed in the cooling flow path 42. According to a modification, three or more reactors may be sequentially placed in the cooling flow path. In this modification, a temperature sensor may be mounted to only a reactor having the highest thermal resistance out of the three or more reactors, or temperature sensors may be mounted to part of reactors including a reactor having the highest thermal resistance out of the three or more reactors. For example, when three reactors are sequentially placed in the cooling flow path, a temperature sensor may be mounted to only a reactor having the highest thermal resistance, or temperature sensors may be mounted to only two reactors having the highest and the second highest thermal resistances. In this modification, it is preferable to place the three reactors in a descending order of the thermal resistance from the downstream side in the cooling flow path.

The following describes the correspondence relationship between the primary components of the above embodiment and the primary components of the present disclosure described in Summary. The reactor L1 and the reactor L2 of the embodiment correspond to the “plurality of reactors”. The cooling flow path 42 of the embodiment corresponds to the “cooling flow path”. The power conversion device 40 of the embodiment corresponds to the “power conversion device”.

In the power conversion device according to the present disclosure, the temperature sensor may be mounted to only the reactor having the highest thermal resistance out of the plurality of reactors. The configuration of this aspect reduces the number of the temperature sensors to be mounted to the power conversion device.

In the power conversion device according to the present disclosure, the reactor having the highest thermal resistance out of the plurality of reactors may be placed in a most downstream portion in the cooling flow path. The most downstream portion of the cooling flow path has the high temperature of the cooling medium flowing through the cooling flow path and accordingly has the small cooling effect. The configuration of placing a reactor having the highest thermal resistance at a location having the smallest cooling effect, detecting the temperature of this reactor, and driving the power conversion device enables the power conversion device to be driven with causing the temperature of the reactor that is placed at a location having the larger cooling effect and that has the lower thermal resistance to be equal to or lower than the allowable maximum temperature.

In the power conversion device according to the present disclosure, a restriction on output of the power storage device may be placed when a temperature detected by the temperature sensor is equal to or higher than a reference temperature. The reference temperature used may be a temperature of a reactor having the highest thermal resistance when an abnormality occurs in the cooling system of a reactor having the lowest thermal resistance out of the plurality of reactors and the reactor having the lowest thermal resistance is heated to the allowable maximum temperature, or a slightly lower temperature than this temperature. This configuration enables the power conversion device to be driven with causing the temperatures of all the plurality of reactors to become equal to or lower than the allowable maximum temperature.

The correspondence relationship between the primary components of the embodiment and the primary components of the present disclosure, regarding which the problem is described in Summary, should not be considered to limit the components of the present disclosure, regarding which the problem is described in Summary, since the embodiment is only illustrative to specifically describes the aspects of the present disclosure, regarding which the problem is described in Summary. In other words, the present disclosure, regarding which the problem is described in Summary, should be interpreted on the basis of the description in Summary, and the embodiment is only a specific example of the present disclosure, regarding which the problem is described in Summary.

The aspect of the present disclosure is described above with reference to the embodiment. The present disclosure is, however, not limited to the above embodiment but various modifications and variations may be made to the embodiment without departing from the scope of the present disclosure.

### INDUSTRIAL APPLICABILITY

The disclosure is applicable to, for example, the manufacturing industries of power conversion devices.

What is claimed is:

1. A power conversion device comprising a plurality of reactors and a cooling flow path in which the plurality of reactors is placed sequentially, the power conversion device being configured to convert electric power from a power storage device, the power conversion device further comprising:
a temperature sensor that is mounted to only part of reactors including a reactor having a highest thermal resistance out of the plurality of reactors.

2. The power conversion device according to claim 1, wherein the temperature sensor is mounted to only the reactor having the highest thermal resistance out of the plurality of reactors.

3. The power conversion device according to claim 1, wherein the reactor having the highest thermal resistance out of the plurality of reactors is placed in a most downstream portion in the cooling flow path.

4. The power conversion device according to claim 2, wherein the reactor having the highest thermal resistance out of the plurality of reactors is placed in a most downstream portion in the cooling flow path.

5. The power conversion device according to claim 1, wherein a restriction on output of the power storage device is placed when a temperature detected by the temperature sensor is equal to or higher than a reference temperature.

6. The power conversion device according to claim 2, wherein a restriction on output of the power storage device is placed when a temperature detected by the temperature sensor is equal to or higher than a reference temperature.

7. The power conversion device according to claim 3, wherein a restriction on output of the power storage device is placed when a temperature detected by the temperature sensor is equal to or higher than a reference temperature.

8. The power conversion device according to claim 4, wherein a restriction on output of the power storage device is placed when a temperature detected by the temperature sensor is equal to or higher than a reference temperature.

9. The power conversion device according to claim 1, wherein the plurality of reactors are reactors included in a plurality of boost circuits that are connected in parallel to each other and that are configured to step up voltage of the electric power from the power storage device and output the electric power of the stepped-up voltage.
